(19) United States
(12) Patent Application Publication
(10) Pub. No.: US 2016/0012884 A1
(43) Pub. Date: Jan. 14, 2016

(54) MEMORY SYSTEM AND METHOD OF OPERATION OF THE SAME

(71) Applicant: Kabushiki Kaisha Toshiba, Minato-ku (JP)

(72) Inventor: Haruki TODA, Yokohama-shi (JP)

(73) Assignee: Kabushiki Kaisha Toshiba, Minato-ku (JP)

(21) Appl. No.: 14/480,951

(22) Filed: Sep. 9, 2014

Related U.S. Application Data
(60) Provisional application No. 62/023,682, filed on Jul. 11, 2014.

(51) Int. Cl. G11C 13/00

(52) U.S. Cl. CPC G11C 13/0002; G11C 13/004; G11C 13/0069

(57) ABSTRACT

A memory system according to the embodiment comprises a memory cell having plural transitionable physical states, the plural physical states including a certain physical state defined as a first physical state, and a physical state held in the memory cell defined as a second physical state, and the memory cell storing plural different data in accordance with differences in transition time from the second physical state to the first physical state.

### CROSS-REFERENCE TO RELATED APPLICATIONS

This application is based upon and claims the benefit of priority from the prior U.S. Provisional Application 62/023,682, filed on Jul. 11, 2014, the entire contents of which are incorporated herein by reference.

### BACKGROUND

1. Field

The embodiment of the present invention relates to a memory system and method of operation of the same.

2. Description of the Related Art

As memories capable of storing mass data for use, variable resistance memories easily formable in three dimensions, such as a ReRAM and an ion memory, have received attention.

A method for further raising the density of information storage in these memories includes forming fine-patterned memory cells. Realization of this method, however, requires high technologies and causes a cost rise inevitably. A method with less cost rise includes realizing multivalue storable memory cells. The use of this method, however, requires ideas for expression of multivalue levels in a memory cell.

### BRIEF DESCRIPTION OF THE DRAWINGS

FIG. 1 is a diagram showing a configuration of a memory system according to the embodiment.

FIG. 2 is a perspective view showing part of a cell array in the memory system according to the embodiment.

FIG. 3 is a diagram showing correspondences between forms of a filament in a memory cell and multivalue levels in the memory system according to the embodiment.

FIG. 4 is a diagram illustrative of contraction of the filament in the memory cell in the memory system according to the embodiment.

FIG. 5 is a diagram illustrative of contraction of the filament in the memory cell in the memory system according to the embodiment.

FIG. 6 is a diagram illustrative of expansion of the filament in the memory cell in the memory system according to the embodiment.

FIG. 7 is a diagram illustrative of expansion of the filament in the memory cell in the memory system according to the embodiment.

FIG. 8 is a graph showing relations between interelectrode voltages and filament gaps at each transition time at the time of reverse bias voltage application in the memory system according to the embodiment.

FIG. 9 is a graph showing relations between transition time and filament gaps at the time of forward bias voltage application in the memory system according to the embodiment.

FIG. 10 is a graph showing relations between transition time and filament gaps at the time of forward bias voltage application in the memory system according to the embodiment.

FIG. 11 is a diagram showing filament gaps expressive of multivalue levels in the memory system according to the embodiment.

FIG. 12 provides graphs showing relations between transition time and filament gaps at the time of an access sequence in the memory system according to the embodiment.

FIG. 13 is a diagram illustrative of a structure of the memory cell in the memory system according to the embodiment.

FIG. 14 is a diagram illustrative of a general concept of a method of detecting a physical form in the memory system according to the embodiment.

FIG. 15 is a flow chart of a write sequence in the memory system according to the embodiment.

FIG. 16 is a flow chart of a read sequence in the memory system according to the embodiment.

FIG. 17 is a circuit diagram of an MLDC in the memory system according to the embodiment.

FIG. 18 is a circuit diagram of a sense amp in the memory system according to the embodiment.

FIG. 19 is an operating waveform diagram associated with the sense amp in the memory system according to the embodiment.

FIG. 20 is a diagram showing a configuration between bit lines and MLDCs in the memory system according to the embodiment.

FIG. 21 is a diagram showing a functional block of a TILE and peripheral circuits in the memory system according to the embodiment.

FIG. 22 is a circuit diagram of a BL dry circuit block in the memory system according to the embodiment.

FIG. 23 is a circuit diagram of a WL dry circuit block in the memory system according to the embodiment.

FIG. 24 is a circuit diagram of a drvSEL circuit block in the memory system according to the embodiment.

### DETAILED DESCRIPTION

A memory system according to the embodiment comprises a memory cell having plural transitionable physical states, the plural physical states including a certain physical state defined as a first physical state, and a physical state held in the memory cell defined as a second physical state, and the memory cell storing plural different data in accordance with differences in transition time from the second physical state to the first physical state.

A memory system and method of operation of the same according to the embodiment is described below with reference to the drawings.

### [Outline of Memory System]

First, a configuration of the memory system according to the embodiment is described.

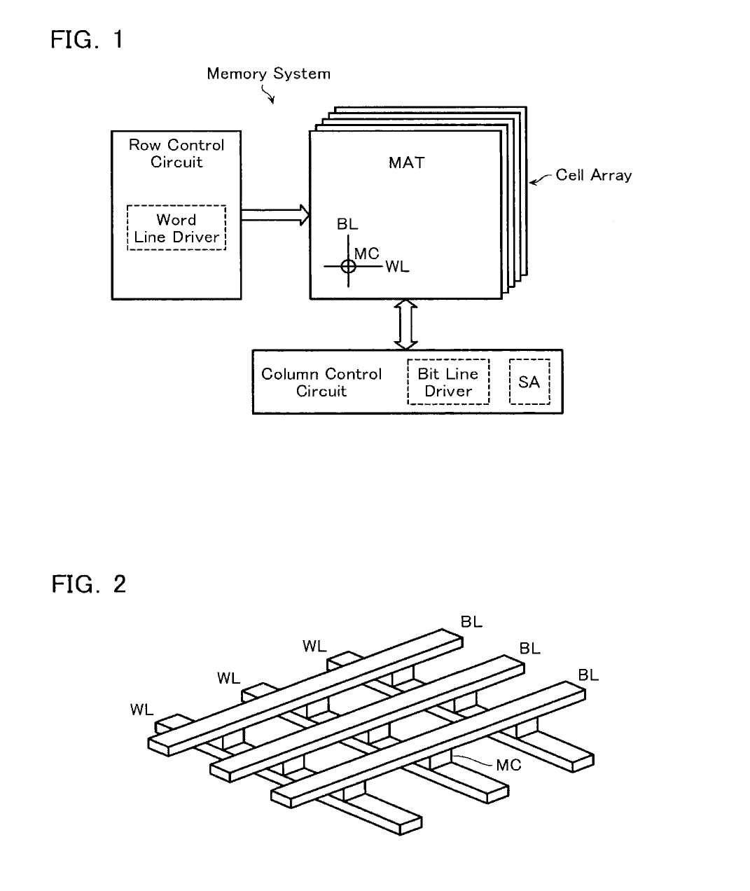

FIG. 1 is a diagram showing the configuration of the memory system according to the embodiment.

This memory system includes a cell array. The cell array includes plural unit cell arrays (hereinafter referred to as “MATs”). Each MAT has plural bit lines BL and plural word lines WL, and plural memory cells MC that can be selected by plural bit lines BL and plural word lines WL.

The bit lines BL in the cell array are electrically connected to a column control circuit, which controls the bit lines BL to write data in the memory cell MC and read data out of the memory cell MC. The column control circuit includes a bit line driver operative to provide the bit line BL with potentials required for data write and data read, and a sense amp SA operative to sense and amplify the current flowing in the memory cell MC at the time of data read to decide the data stored in the memory cell MC.

On the other hand, the word lines WL in the cell array are electrically connected to a row control circuit, which selects the word line WL at the time of data write to the memory cell MC and data read from the memory cell MC. The row control circuit includes a word line driver operative to provide the word line WL with potentials required for data write and data read. The row control circuit is contained in a control unit together with the column control circuit.

Hereinafter, a series of processing for writing data in the memory cell may also be referred to as a “write sequence”, and a series of processing for reading data from the memory cell as a “read sequence”. Data write and data read may also be called by their generic term, “access”, and bit lines BL and word lines WL by their generic term, “selection lines”. An access-targeted memory cell may also be referred to as an “access cell”, and selection lines connected to the access cell as “access selection lines”.

Next, a structure of the cell array of the embodiment is described.

FIG. 2 is a perspective view showing part of the cell array in the memory system according to the embodiment.

The cell array includes plural bit lines BL extending in the column direction, plural word lines WL extending in the row direction, and plural memory cells MC provided at the intersections of plural bit lines BL and plural word lines WL. Thus, the cell array has a structure of the cross point type.

### [Realizing Multi-Valued Memory Cells and Associated Write/Read]

The following description is given to an outline of realizing multi-valued memory cells and the associated write/read.

Hereinafter, an ion memory is mainly described by way of example.

Realizing a multi-valued memory cell requires setting the number of multivalue levels to the extent that ECC (Error Correcting Code) can compensate for the instability of data storage. The embodiment utilizes the point that a form transition of a filament in the memory cell is a time-dependent phenomenon. Namely, realizing multi-valued memory cells utilizes the fact that transition time from plural different physical states to a certain physical state differs from each other. In this case, reading data from the memory cell is destructive read, though the utilization of the above nature leads to a general method of realizing multi-valued memory cells. Therefore, the below-described concept of realizing multi-valued memory cells is also applicable widely to other cases than the memory system using the ion memory.

The following description is given to a method for realizing plural physical states, which turn to multivalue levels in a variable resistance memory cell that stores data using formation of a metallic filament in a solid phase.

Physical quantities such as resistances and currents are unstable in values and not appropriate to express multivalue levels. On the other hand, forms of a filament are relatively stable. Therefore, in the embodiment, forms of a filament are used to express multivalue levels.

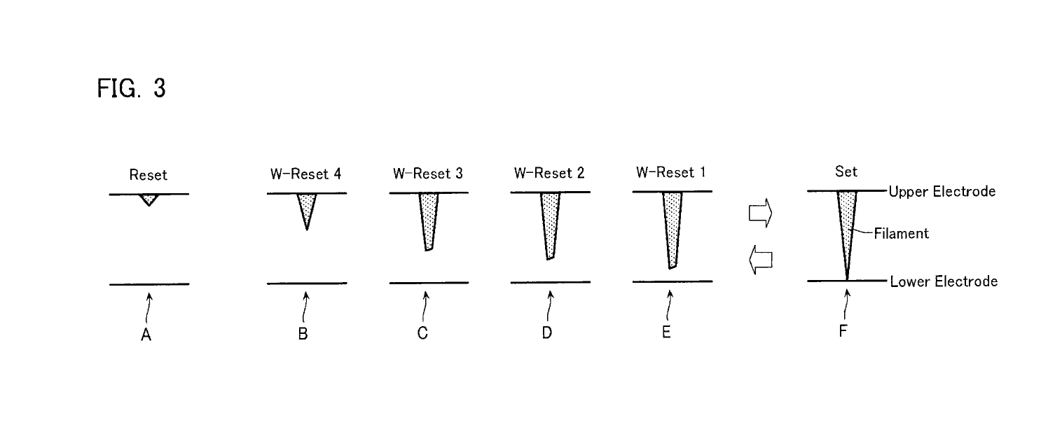

FIG. 3 is a diagram illustrative of correspondences between forms of a filament in a memory cell and multivalue levels in the memory system according to the embodiment. FIG. 3 shows six forms of a filament.

The form in A of FIG. 3 is a reset state (Reset) (third physical state), that is, a high-resistance state in which the filament almost vanishes. The form in F of FIG. 3 is a set state (Set) (first physical state), that is, a low-resistance state in which the filament makes contact with the lower electrode. Four forms in B-E of FIG. 3 are states close to the set state, that is, weak reset states (W-Reset) (second physical state) in which gaps present between the filament and the lower electrode. In a word, the reset state and the weak reset state are off-states that cause no flow of cell current while the set state is an on-state that causes a flow of cell current as is said. A transition arises reversibly between the reset state and the set state for the first time when placed in a large electric field. A transition arises reversibly between the weak reset state and the set state even in a relatively small electric field.

The embodiment makes the reset state and four weak reset states correspond to data, thereby realizing 5-values/cell. Memory cells in the reset state and weak reset states, however, have almost the same resistance values. Therefore, how to detect differences in filament form in those states presents a problem. In addition, four weak reset states relate to a continuous-transition making form of the filament, which is sectioned in certain ranges. Accordingly, an error inevitably arises between adjacent states. In this regard, data handling by ECC is required as described above.

Next, in the form of the filament, the length of the filament, that is, the gap between the filament and the lower electrode (hereinafter referred to as a “filament gap”. In addition, the length of the filament gap is referred to as a “gap length”) is used to express multivalue levels. On the premise of the above, the following description is given to how to form and detect a filament.

In the embodiment, the below-described physical phenomenon is simplified to yield a model as a work hypothesis, and the description is given on the premise of this hypothesis.

As for the metal that forms the filament, it is considered that the metal of the electrode is ionized and migrates in the solid phase between the electrodes to cause dissociation and accumulation. There is a potential gap that allows ions to start migration. In an electric field having a potential that exceeds the potential gap, ions can migrate. In the embodiment, based on this image, the physical phenomenon is modeled as below.

(1) The dissociation and accumulation of metal ions at the filament tip depends on a parameter, that is, the strength E of the electric field at the filament tip. There is an electric field potential gap Vc having a critical strength at the filament tip surface. As the metal migration in the filament is small at the magnitude less than Vc, the filament cannot expand/contract.

(2) The quantity n of metal ions per unit time accumulated from the electrode and the medium at the time of expansion/contraction of the filament is proportional to the magnitude of the electric field E−Ec having a potential of Vc or higher at the filament tip surface. The magnitude of expansion/contraction of the filament per unit time is proportional to n. The electric field Ec having an almost constant critical potential Vc varies in accordance with the gap length δ.

The above is the work hypothesis of the embodiment.

In the embodiment, plural gap lengths g are used to express multivalue levels. The plural gap lengths g each are formed on the basis of the set state as the initial state. Contraction of the filament from the set state requires application of a reverse bias voltage between the electrodes in a direction of the electric field effective in contraction of the filament. Therefore, formation of the filament can be controlled by the magnitude of the voltage applied between the electrodes or the application time thereof.

On the other hand, detection of the gap length g requires application of a constant forward bias voltage between the electrodes in a direction of the electric field effective in expansion of the filament so that the memory cell makes a transition to the set state. Detection of the time since the beginning of application of the voltage between the electrodes until the transition to the set state makes it possible to separately decide multivalue levels in accordance with differences in the time. This method, however, utilizes the form transition of the filament. In other words, data read of the embodiment is destructive read. Therefore, rewrite is then required to return the gap length δ to the original magnitude.

The following description is given to a method of quantifying the form transition of the filament and controlling the form transition. As the premise of the above, quantities that characterize the form of the filament and the environment are defined.

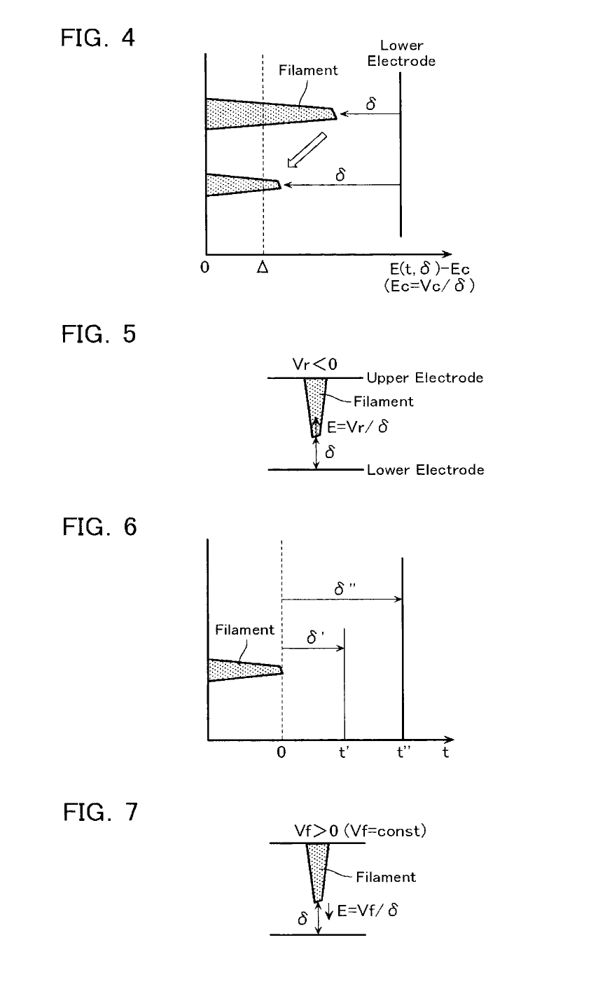

FIGS. 4 and 5 are diagrams illustrative of contraction of the filament in the memory cell in the memory system according to the embodiment. FIGS. 4 and 5 show the process of application of a reverse bias voltage to the memory cell in the set state to cause contraction of the filament. In FIG. 4, Δ indicates a value that almost causes no form transition of the filament if E−Ec is smaller than Δ. In FIG. 5, Vr is the magnitude of a negative interelectrode voltage on the basis of the potential at the lower electrode. When the magnitude of the electric field at the filament tip is denoted with E (=Vr/δ), the direction of the electric field acts in a direction effective in contraction of the filament as shown in FIG. 5. When the time since the beginning of application of an interelectrode voltage is denoted with t, E is a function of t and δ, that is, E(t, δ). The filament contracts until the difference between E and the electric field Ec having a metal-ion migrating potential Vc gets closer to Δ as shown in FIG. 4. In the embodiment, the relation between the filament form transition and E is utilized to set multivalue levels in a memory cell.

FIGS. 6 and 7 are diagrams illustrative of expansion of the filament in the memory cell in the memory system according to the embodiment. FIGS. 6 and 7 show the process of application of a forward bias voltage to the memory cell to cause expansion of the filament so that the memory cell makes a transition to the set state. In FIG. 7, Vf is the magnitude of a positive interelectrode voltage on the basis of the potential at the lower electrode. The direction of the electric field of Vf acts in a direction effective in expansion of the filament as shown in FIG. 7. When a constant Vf larger than Vc is applied between the electrodes, E−Ec increases along with expansion of the filament to accelerate the expansion of the filament.

In the following description, as shown in FIG. 6, the time since the beginning of application of a voltage between the electrodes until a filament gap of the length δ′ vanishes is represented by t′, and the time since the beginning of application of a voltage between the electrodes until a filament gap of the length δ″ vanishes is represented by t″, for example. In addition, the time required for a transition from a certain filament form to another filament form may also be referred to as “transition time”. For example, if a filament form makes a transition when a constant voltage is applied to a memory cell, the application time of the voltage to the memory cell and the transition time have the same value.

Next, formularization of the contraction process of a filament is described. As described later, setting of multivalue levels in a memory cell is realized by causing contraction of the filament. In a word, the formulae herein shown mainly relate to writing data in the memory cell.

Expressions 1-3 are numerical formulae associated with the contraction process of the filament.

E=Vr/δ [Expression 1]

E=Ec;

Ec=Vc/δ [Expression 2]

n=α′(E−Ec), E−Ec=(Vr−Vc)/δ

d(δ)=nd(t)=(α′(Vr−Vc)/δ)d(t)

δ=(2α′(Vr−Vc)t)^{1/2}

g=(2α′(u−Vc)T)^{1/2} [Expression 3]

The migration quantity n of metal ions per unit time is proportional to the magnitude E−Ec of the electric field. This proportionality constant is denoted with α′. As shown in Expressions 1 and 2, E−Ec is inversely proportional to the gap length δ. Accordingly, these small quantities and small time have proportional relations therebetween. When these relations are used to solve a differential equation, a relation between δ and Vr and t is obtained. At t=0, an initial state of δ=0 is reached.

From the above, the gap length g can be represented as shown in Expression 3 by the magnitude u of the reverse bias voltage and the application time T. Therefore, setting of a level in a memory cell can be controlled by u or T.

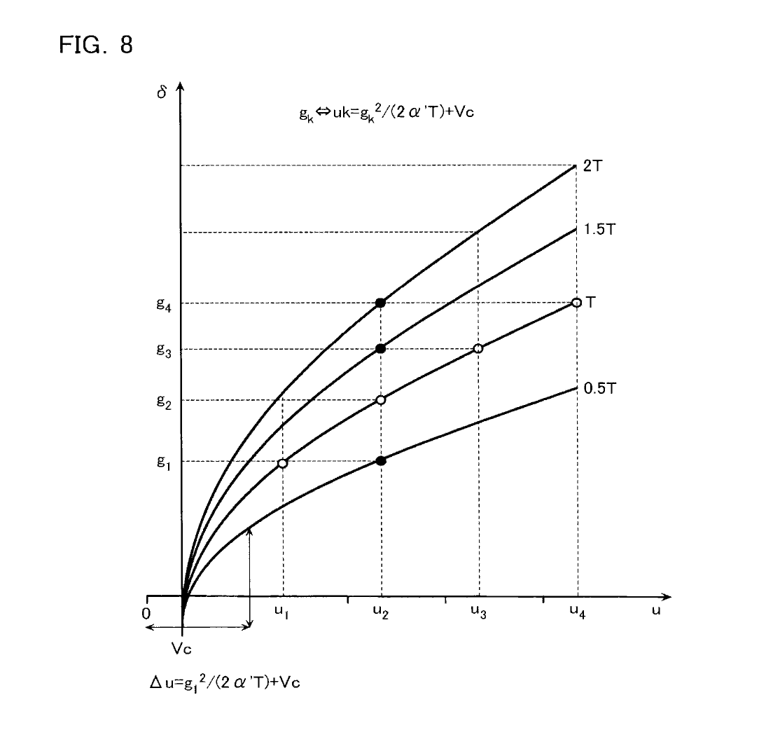

FIG. 8 is a graph showing relations between interelectrode voltages and filament gaps at each transition time at the time of reverse bias voltage application in the memory system according to the embodiment.

When the gap lengths g are used as physical states to express multivalue levels as in the embodiment, the application time of the interelectrode voltage is kept constant, and then the magnitude of the interelectrode voltage is adjusted. Otherwise, the magnitude of the interelectrode voltage is kept constant, and then the application time of the interelectrode voltage is adjusted. The above two methods can be used to form a desired gap length g. In this regard, these two methods have the same effect. Therefore, at the time of data write, either of the methods can be selected at each memory system in consideration of the easiness of control and so forth.

As can be found from FIG. 8, the gap lengths g (open circles in FIG. 8) at interelectrode voltages u₁-u₄ in the case of the application time T are coincident with the gap lengths g (filled circles in FIG. 8) at an interelectrode voltage u₂ in the case of the application time 0.5T-2T. This point is clear from the calculation formulae in Expression 3. The starting point of the interelectrode voltage at δ=0 is Vc. Accordingly, the interelectrode voltage on the lateral axis of the graph has a certain bias of Vc. This point should be noted.

Two methods of forming a filament having a gap length δ have the following points to notice.

In the case of the voltage adjusting method, the time required for formation of the filament is extended to some extent. Then, the adjustment intervals for the magnitude of the interelectrode voltage are determined almost constant so as to prevent fluctuations in the magnitude and the application time of the interelectrode voltage from causing any overlap in the magnitude of the gap length g.

In the case of the time adjusting method, the interelectrode voltage is determined appropriately to smoothly advance the formation of the filament. In this case, similar to the voltage adjusting method, the adjustment intervals for the application time of the interelectrode voltage are determined almost constant so as to prevent fluctuations in the magnitude and the application time of the interelectrode voltage from causing any overlap in the magnitude of the gap length g.

Either of the methods exerts no large influence if the product of the disturbance of the interelectrode voltage u and the application time is around equal to the product of the magnitude of the minimum application voltage u₁ and the minimum application time. In the case of the example of FIG. 8, it is ˜u₁×0.5T as shown with the arrow in FIG. 8.

Next, formularization of the expansion process of a filament is described. As described later, decision of multivalue levels in a memory cell is realized by causing expansion of the filament. In a word, the formulae herein shown mainly relate to reading data from the memory cell.

Expressions 4 and 5 are numerical formulae associated with the expansion process of the filament.

n=α(E−Ec), E−Ec=(Vf−Vc)/δ

−d(δ)=nd(t)=(α(Vf−Vc)/δ)d(t)

δ=(−2α(Vf−Vc)t+g²)^{1/2} [Expression 4]

δ=0;

τ=g²/(2αv) [Expression 5]

In the case of level decision, it is difficult to realize it by adjusting the interelectrode voltage as in the case of level setting. Therefore, levels are decided based on differences in transition time to a certain form at the time of application of a certain interelectrode voltage. Specifically, a set level is decided by applying a certain interelectrode voltage to a memory cell and detecting the transition time to the set state.

If the interelectrode voltage at the time of multivalue level decision is a forward bias voltage Vf, the differential equation in Expression 4 is established between a reduction in the gap length δ and the accumulation quantity n of metal ions per unit time. When this differential equation is solved, a relational expression among δ, Vf, time t and a gap length g is obtained. Expression 5 becomes δ=0 at the set state. Accordingly, the time until a filament having a gap length g vanishes is denoted with τ, and an interelectrode voltage applied at the time of level decision is denoted with Vf=Vread, v=Vread−Vc.

As described above, the form of a filament having a gap length g in a memory cell can be decided based on the vanishing time τ.

Next, methods of expressing multivalue levels based on gap lengths g are described.

There are various methods of expressing multivalue levels while two expressing methods are mainly described below. The two expressing methods herein referred include a method of sectioning gap lengths δ at even intervals (hereinafter referred to as an “even-interval gap-length-dividing method), and a method of sectioning the vanishing time of the filament having a gap length δ, that is, the transition time to the set state at even intervals (hereinafter referred to as an “even-interval time-dividing method” or simply a “time-dividing method”).

The even-interval gap-length-dividing method and the even-interval time-dividing method have the following large differences therebetween.

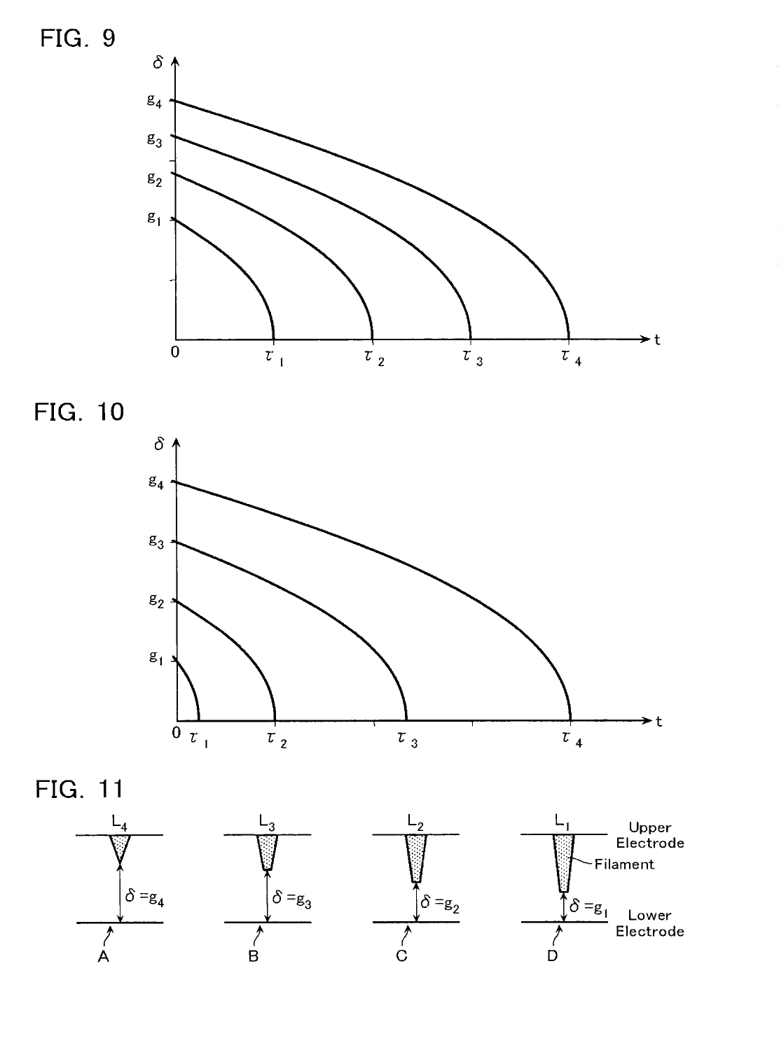

FIGS. 9 and 10 are graphs showing relations between transition time and filament gaps at the time of forward bias voltage application in the memory system according to the embodiment. FIG. 9 shows an example of the even-interval time-dividing method and FIG. 10 shows an example of the even-interval gap-length-dividing method.

In general, the filament form hides as the electric physical state. Therefore, setting of gap lengths g at even intervals has no electric meaning. In a word, for decision of gap lengths g, division of the vanishing time at even intervals rather has a meaning. In this regard, the even-interval time-dividing method is rather reasonable as is said.

In the case of the even-interval time-dividing method, as shown in FIG. 9, gap lengths g are set so that the vanishing time t aligns at even intervals. Namely, seen from a quadratic function indicative of reductions in gap length δ, the vanishing time t of a filament having each gap length g is set so as to become equal to a multiple of the difference in vanishing time t between filaments having each gap length g. In the case of the even-interval time-dividing method, setting intervals of gap lengths δ are small. It is, though, possible to decide the vanishing time until the set state in a linear relation. Therefore, filament forms can be decided easily. For protecting the distribution region of each gap length g from the voltage disturbance, it is desired to set the gap length g within a range of gap lengths δ having larger values.

In the case of the even-interval gap-length-dividing method, as shown in FIG. 10, it is possible to ensure larger margins between gap lengths g. Generally, leaving memory cells free may increase gap lengths δ, and overlaps of distribution regions of each gap length g may increase and deteriorate the retention as is considered. In this regard, in the case of the even-interval gap-length-dividing method, it is possible to set wider margins between gap lengths g. Therefore, it is easy to ensure the retention compared to the even-interval time-dividing method. A variation by the square of the gap length δ, however, changes the transition time to the set state. Therefore, compared to the even-interval time-dividing method, the difference in time required for decision between gap lengths g becomes larger. Thus, it is required to ensure longer sense time and sufficiently control the resolution.

Next, an access method in the memory system according to the embodiment is described.

In consideration of the practicability, access by the even-interval time-dividing method is described here.

FIG. 11 is a diagram showing filament gaps expressive of multivalue levels in the memory system according to the embodiment.

Here, as levels set in a memory cell, five levels are prepared, including the filament-almost-vanished reset state, and four weak reset states L₁-L₄ having gaps g₁-g₄ as shown in FIG. 11. Hereinafter, the weak reset states L₁-L₄ that become important at the time of configuration of multivalue levels are mainly described.

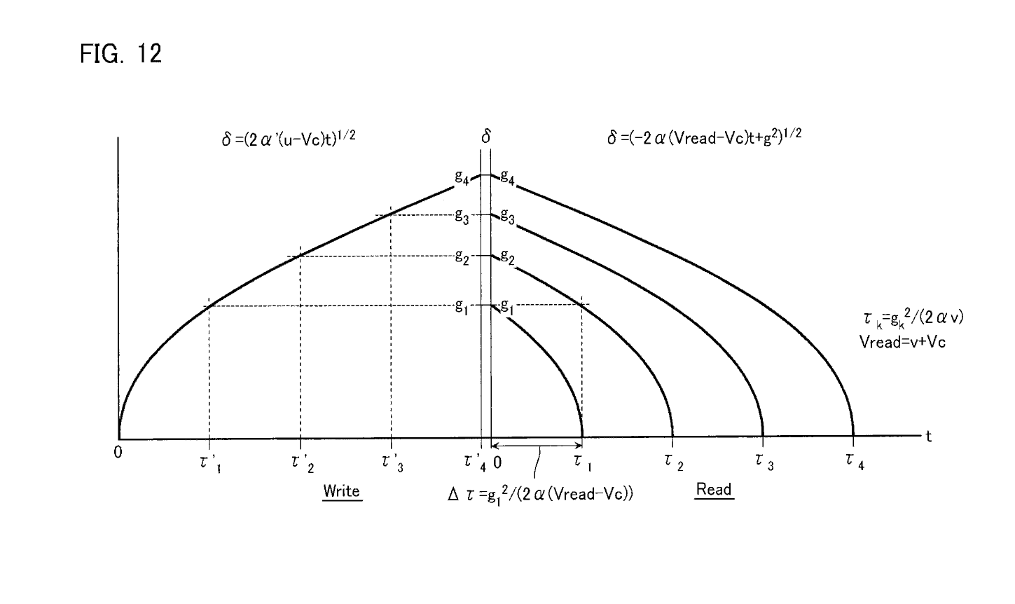

FIG. 12 provides graphs showing relations between transition time and filament gaps at the time of an access sequence in the memory system according to the embodiment. The left part of FIG. 12 is a graph at the time of level setting while the right part of FIG. 12 is a graph at the time of level decision. Each graph shows transition time t along the lateral axis and gap lengths δ along the vertical axis.

Formation of a filament gap is performed by applying a reverse bias voltage u to a memory cell in the set state. The gap length δ varies as a function of time t to the ½-th power. When the voltage u is continuously applied to the memory cell, the gap length reaches g₁-g₄ as shown in the left part of FIG. 11 at each point of time τ′₁-τ′₄ aligning almost at even intervals. In a word, when an appropriate certain voltage u is applied to the memory cell to make a filament form transition only for any of time τ′₁-τ′₄, it is made possible to set the gap length g₁-g₄ corresponding to the weak reset state L₁-L₄ shown in FIG. 11.

Detection of a filament gap is performed by, opposite to the time of formation of the filament gap, applying a forward bias voltage to the memory cell to vanish the filament. At this time, the filament gap varies as a function of the initial value g of the gap length δ, the interelectrode voltage Vread, and the transition time t. The interelectrode voltage Vread has almost the same magnitude as the voltage u at the time of filament gap formation. Until the filaments having gap lengths g₁-g₄ reach the set state, they require transition time τ₁-τ₄, respectively. In a word, when an appropriate certain voltage Vread is applied to the memory cell to make a filament form transition only for any of time τ₁-τ₄, it is made possible to detect the gap length δ. Thus, the level set in the memory cell can be detected.

At the time of gap length δ detection, the disturbance margin of a memory cell is associated with the forward bias disturbance, which is time-dependent. This disturbance, though, can be limited to failed decision between adjacent levels at most. Therefore, in the case of the memory system according to the embodiment, an ECC capable of checking and correcting failed decision between adjacent levels is used to ensure the reliability of data.

The following description is given to an example of a method of stably forming a filament in a memory cell.

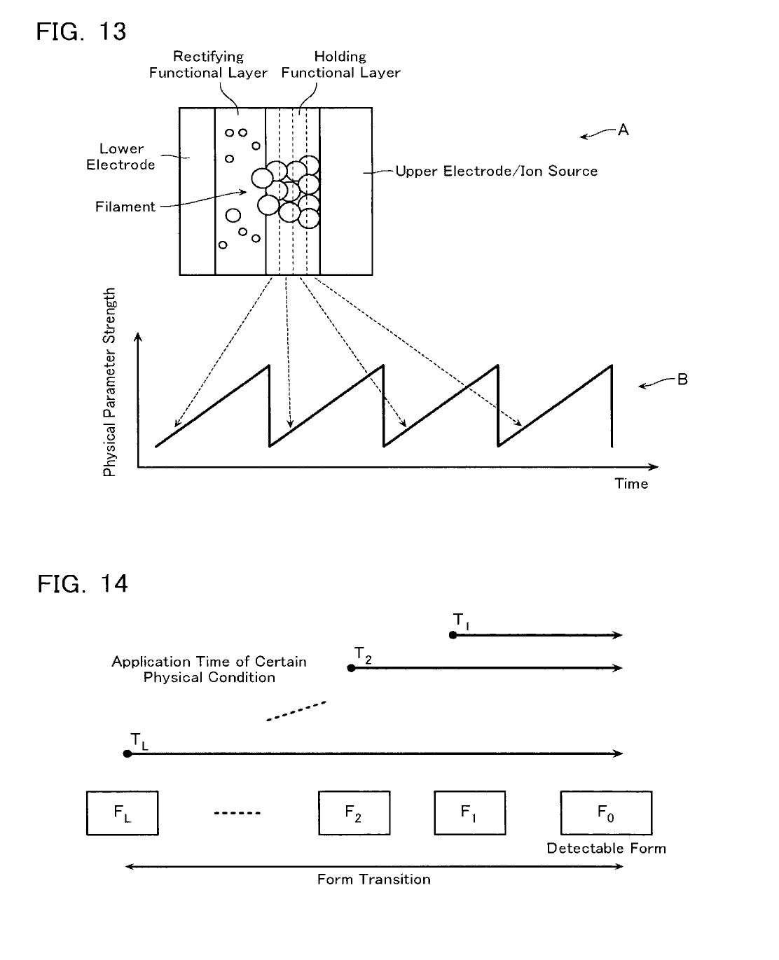

FIG. 13 is a diagram illustrative of a structure of the memory cell in the memory system according to the embodiment. FIG. 13 shows an example of the ion memory provided as a memory cell, similar to the above description.

The memory cell in the ion memory includes an upper electrode serving as an ion source, a lower electrode, and a solid phase sandwiched between these upper and lower electrodes in which a filament is formed as shown in A of FIG. 13. The solid phase further includes a holding functional layer and a rectifying functional layer stacked from the upper electrode to the lower electrode. The memory cell is brought into a low-resistance state by a filament formed in the holding functional layer and the rectifying functional layer by application of electric energy. Holding the filament form is performed by the holding functional layer.

Therefore, the holding functional layer is not deposited uniformly but deposited with fluctuations of physical parameter strengths of materials so as to modulate the coefficient of expansion/contraction of the filament over the application time of the interelectrode voltage. The physical parameter strengths herein may include gas flow rates, temperatures, plasma compositions, electric fields, magnetic fields and so forth, which exert influences on the time difference at the time of expansion/contraction of the filament without loss of the characteristic of the holding functional layer. For example, when a physical parameter is fluctuated as shown in a graph in B of FIG. 13, four heterogeneous layers are formed in the holding functional layer, causing similar heterogeneity in the time required for expansion/contraction of the filament. This heterogeneity serves as a time barrier for a transition between levels. As a result, the borderline between levels is made clear so that failed setting between levels can be improved.

When filament forms are used to express multivalue levels in this way, it is desired to change physical situations at every level so that the difference between levels is made clear.

Although realizing multi-valued memory cells in the ion memory has been described until now, realizing multi-valued memory cells is once summarized here from the general viewpoint.

The embodiment is characterized in that expression of multivalue levels uses the magnitude of the filament gap length, which is an electrically directly undetectable physical state.

FIG. 14 is a diagram illustrative of a general concept of multivalue level detection in the memory system according to the embodiment.

FIG. 14 shows L metastable, electrically directly undetectable physical states by forms F₁-F_{L}, and an electrically directly detectable physical state by a detectable form F₀. In addition, it shows transition time from the forms F₁-F_{L} to the detectable form by T₁-T_{L}. The forms F₁-F_{L} are aligned in the order of magnitude of time required for transition to the detectable form.

Formation of the forms F₁-F_{L} uses the measurable form F₀ as the initial state, and changes physical conditions from the initial state to make transitions to the forms F₁-F_{L}. These forms F₁-F_{L} are metastable states and accordingly, after the formation, those forms can be maintained even if the physical conditions until then are removed. This is setting of levels.

Decision of a level set in a memory cell utilizes the relaxation time of the metastable state. Application of a certain physical condition to the memory cell can accelerate the relaxation time from the metastable state to the initial state. The presence in any of metastable states causes a difference in relaxation time from others. In a word, a certain physical condition is applied to memory cells in the forms F₁-F_{L} to make transitions to the detectable form F₀ to detect any physical parameters when they reach the detectable form F₀. Then, comparison of the transition time from the forms F₁-F_{L} to the detectable form F₀ makes it possible to decide the level set in the memory cell.

If the transition between forms is reversible relative to a modification of the physical condition, level decision can be realized in the reversed process to level setting. Namely, in any case, the difference in transition time between forms can be used in distinction. On the other hand, if the form transition is irreversible relative to a modification of the physical condition, application of different physical conditions is required in level decision and level setting, and detection of an indistinct form is performed based on time.

### [Specific Example of Memory System]

Next, as the premise for describing a specific example of the memory system in the case of multivalue levels expressed by filament forms, policies of data read and write in the memory system of the embodiment are shown below.

(1) As expansion/contraction of a filament is considered a reversible process dependent on the direction of the electric field, write and read is both executed by the even-interval time-dividing method with the use of differences in application time of a certain interelectrode voltage.

(2) Data in a memory cell is read out in read operation by destructive read. Therefore, at the time of the read sequence, rewrite operation is executed to re-set the level after read operation. In the embodiment, the rewrite operation is made the same as write operation to set the level at the time of the write sequence, thereby simplifying peripheral circuits.

(3) In write operation and read operation, voltages having almost the same magnitude with opposite polarities are applied to a memory cell.

(4) A multivalue level holding register corresponding to an access cell is provided.

(5) Write operation also makes it possible to make parallel access to plural memory cells. At that time, applications of interelectrode voltages to plural access cells are started simultaneously, and stopped based on the application time of interelectrode voltages to the memory cells, which is sectioned in accordance with the set-intended levels.

(6) In read operation, the transition time until the memory cell makes a transition to the set state is sectioned so as to correspond to multivalue levels, which multivalue levels each are held in the register as data.

(7) In the read sequence, data held in the register is used as data at the time of read operation and at the time of rewrite operation.

Next, the write sequence and the read sequence of the embodiment are described.

The embodiment uses four biases in the write sequence and the read sequence, including: a “forward bias” for making a transition from the reset state to the set state; a “reverse bias” having the same magnitude as the set voltage for making a transition from the set state to the reset state; a “weak forward bias” for making a transition from the weak reset state to the set state; and a “weak reverse bias” for making a transition from the set state to the weak reset state. Among those, the forward bias and the reverse bias have the same magnitude with mutually opposite polarities. The weak forward bias and the weak reverse bias have the same magnitude with mutually opposite polarities. In addition, the forward bias is an electric field in a direction effective in expansion of a filament while the reverse bias is an electric field in a direction effective in contraction of the filament.

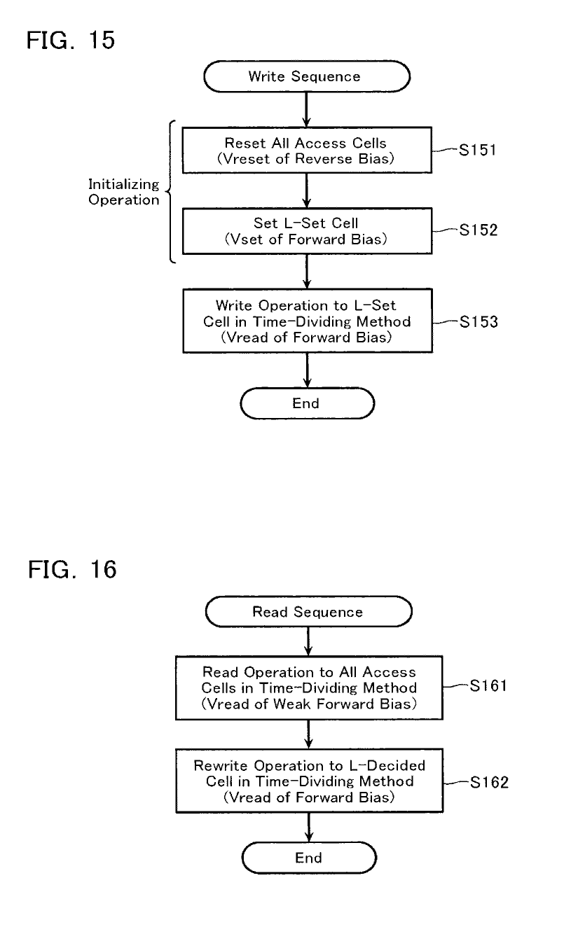

FIG. 15 is a flow chart of a write sequence in the memory system according to the embodiment.

The write sequence includes initializing operation, which is performed at first at steps S151 and S152.

In initializing operation, at first, at step S151, all access cells are applied with a reverse bias voltage V=Vset−Vreset to make a transition to the reset state (high-resistance state).

Subsequently, at step S152, all multivalue level-set-intended memory cells of the access cells (hereinafter multivalue level-set-intended access cells are referred to as “L-set cells”) are applied with a forward bias voltage V=Vset−Vreset to make a transition to the set state (low-resistance state). In the write sequence of the embodiment, this set state is used as the starting point to set a desired level in each access cell.

Subsequently, at step S153, write operation in the time-dividing method is performed. In a word, all L-set cells are applied with a weak reverse bias voltage U=Vread smaller than the voltage V. In this state, at each memory cell, at the time when the transition time corresponding to the set-intended level L elapsed since the beginning of application of the weak reverse bias voltage, the application of the weak reverse bias is stopped. Thus, in each L-set cell, a filament in a form corresponding to the set-intended level is formed.

The above is the write sequence of the embodiment.

FIG. 16 is a flow chart of a read sequence in the memory system according to the embodiment.

The read sequence includes read operation in the time-dividing method, which is performed at first at step S161. In a word, all access cells are applied with a weak forward bias voltage Vread. In this state, at each access cell, the transition time until the set state is detected with application of time ranges. Thus, the level set in the memory cell can be detected. In addition, memory cells making no transition to the set state are decided here as set in the reset state.

Subsequently, at step S162, rewrite operation in the time-dividing method is performed. In a word, all access cells decided in read operation to have set multivalue levels (hereinafter access cells decided to have set multivalue levels are referred to as “L-decided cells”) are applied with the weak reverse bias voltage U =Vread. In this state, at each L-decided cell, until the transition time corresponding to the re-set-intended level elapsed since the beginning of application of the weak reverse bias voltage, the weak reverse bias is applied. Thus, each L-decided cell includes a filament formed therein in a form corresponding to the set-intended level. This rewrite operation includes the same processing as that of the write operation in the write sequence.

The above is the read sequence of the embodiment.

The read operation in the read sequence is destructive read as described above. In this regard, this read operation cannot be used to verify in write operation and rewrite operation. Accordingly, always considering possible occurrences of failed setting of levels in memory cells, the embodiment requires ECC-utilized error check and correction.

The following description is given to specific configurations of peripheral circuits containing control units for memory cells according to the embodiment.

First, an example of a circuit block operative to write and read multiple values by the time-dividing method is described. Hereinafter, this circuit block is referred to as an “MLDC” (Multi Level Data Circuit).

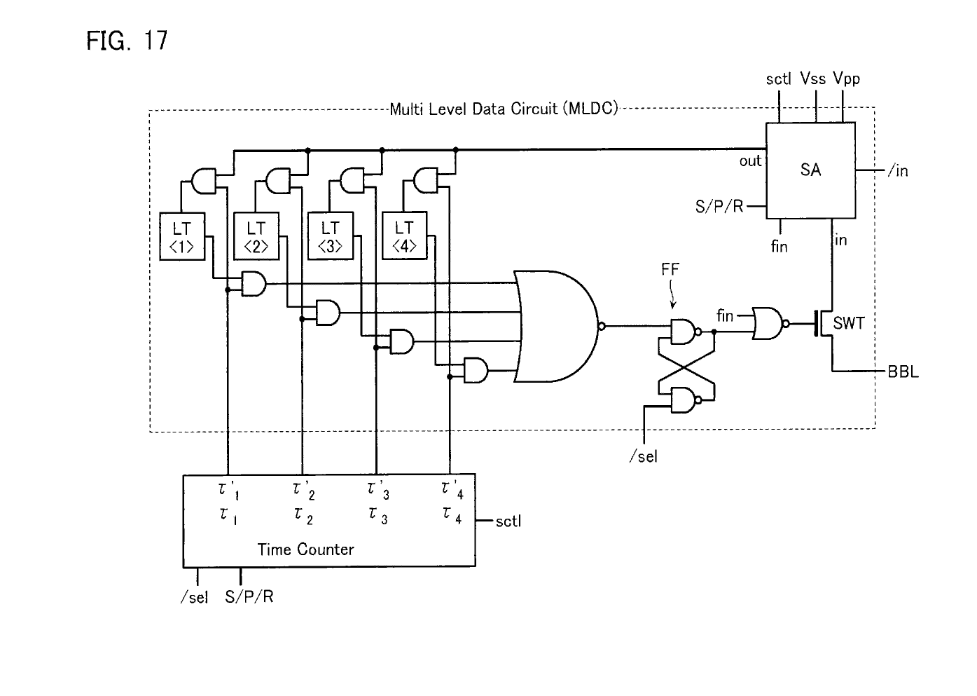

FIG. 17 is a circuit diagram of the MLDC in the memory system according to the embodiment. An area surrounded by the dashed-line in FIG. 17 includes the MLDC.

The MLDC is provided at each of memory cells to be accessed simultaneously. For example, if a cell array is divided into plural blocks of plural memory cells, it is provided at each block. Thus, the memory system is possible to perform setting and decision of levels in parallel, which are different at each access cell.

All MLDCs in the memory system share a time counter. Although not shown in the figure, latches LT<1>->4> contained in the multivalue level holding register in the MLDC include paths for externally setting data to be written in a memory cell at the time of write operation (containing rewrite operation).

The MLDC includes a sense amp SA that detects the transition time at the time of read operation and serves as a current path at the time of write operation; latches L<1>-<4> that apply the transition time detected at the sense amp SA in time ranges and hold the result; and a transistor operative to electrically connect/disconnect between the MLDC and a block bit line BBL, and a logic circuit operative to control it.

The sense amp SA decides the state of the memory cell connected to the block bit line BBL and switches between signal paths at the time of program. Namely, when R of control signals S/P/R is received, it performs detecting operation in read operation. In detecting operation, currents flowing in input signals, in and /in, are compared with each other, and output signals, out and fin, in accordance with the result are provided to external. In this detecting operation, the block bit line BBL is supplied with the voltage Vread from a power source Vpp serving as the driving power source. When the memory cell turns to the set state, the output signal, out, makes a transition to ‘H’, and the output signal, fin, makes a transition from ‘L’ to ‘H’. Thus, the transistor SWT turns off and electrically disconnects the input signal, in, to the sense amp SA from the block bit line BBL. The input signal, /in, is supplied with the reference current for detecting the state of the memory cell. This detecting operation is repeated by a control signal, sctl, fed from the time counter. The control signal, sctl, is a general term of plural signals provided in synchronization with timing τ₁-τ₄.

When S of control signals S/P/R is received, it performs set operation in initializing operation. In set operation, the input signal, in, to the sense amp SA is supplied with the voltage Vset from the power source Vpp serving as the driving power source. In set operation, the output signals, out and fin, make transitions to ‘L’. Thus, the memory cell connected to the block bit line BBL makes a transition to the set state (low-resistance state).

When P of control signals S/P/R is received, it performs program operation in write operation or rewrite operation. In program operation, the input signal, in, is connected to the power source Vss to apply a reverse bias voltage or a weak reverse bias voltage to the memory cell connected to the block bit line BBL. In program operation, the output signals, out and fin, make transitions to ‘L’. Thus, after a lapse of certain time, the block bit line BBL and the input signal, in, are electrically disconnected from each other by the transistor SWT to finish program operation.

The multivalue level holding register includes latches LT<1>-<4>. The control unit decides the level set in the access cell based on which one of the latches LT<1>-<4> holds ‘1’. The latch LT<1> corresponds to time τ₁ or τ′₁, the latch LT<2> to time τ₂ or τ′₂, the latch LT<2> to time τ₃ or τ′₃, and the latch LT<4> to time τ₄ or τ′₄ to control write operation/read operation in the time-dividing method.

In read operation when the control signal R is received, an AND gate is used to get AND of the output signal, out, from the sense amp SA and the time τ or τ′. The AND is used as the input signal to each latch LT. In read operation, all latches LT<1>-<4> hold ‘0’ to turn to the standby state. The sense amp SA updates the output signal, out, in synchronization with the time τ generated from the time counter at each of the time ranges corresponding to multivalue levels. Then, the latch LT corresponding to the time τ holds ‘1’ when the output signal turns to out=‘1’. In a word, the control unit makes all latches LT hold ‘0’ until the access cell makes a transition to the set state and, at the timing of the transition to the set state, it makes the corresponding latch LT hold ‘1’. Then, the control unit decides the level in the access cell in accordance with the data pattern in the latches LT<1>-<4>.

In set operation when the control signal S is received, the latches LT<1>-<4> particularly relate no operation.

In program operation when the control signal P is received, the control unit utilizes the data held in these latches LT<1>-<4> to set a level in the access cell connected to the block bit line BBL. The outputs from the latches LT<1>-<4> are associated with the timing τ′₁-τ′₄ fed from the time counter to get AND thereof, and then fed into a NOR gate in parallel. The output from the NOR gate is fed to a flip-flop circuit FF. Thus, the output from the flip-flop turns to ‘H’.

The output from the NOR gate turns to ‘L’ when the data held in the latch LT is ‘1’ and the timing τ′ corresponding to this latch LT is coincident therewith. Hereinafter, the output from the flip-flop FF turns to ‘H’. In this case, the ‘H’-turned output from the NOR gate and the always-‘L’ output signal, fin, turn off the transistor SWT to electrically disconnect the block bit line BBL from the power source Vss. Thus, application of the weak reverse bias voltage to the access cell is stopped.

In this program operation, a reverse bias voltage of almost Vread is applied to the access cell so that a filament corresponding to the time τ′ is formed by the program in the time-dividing method.

A control signal, /sel, is a signal for resetting the flip-flop FF prior to program operation and for resetting the time counter at the same time to get ready for the next operation. The time counter receives the control signal S/P/R as the input. The time counter is inoperable in the case of the control signal S. It generates the timing τ′ in the case of the control signal P and generates the timing τ and the control signal, sctl, in the case of the control signal R.

The sense amp SA in the MLDC is described next in detail.

The embodiment uses the sense amp of the current comparison type so that the state of the memory cell can be monitored at high speeds by small current comparison at the time of read operation. In the embodiment, however, for further enhancing the sensitivity of the sense amp SA, the inflow of current into a current mirror circuit on the cell current input side is made the same as that on the reference current side so that the resistance value of the cell can be reflected more. The following description is given to a sense amp SA that compares the cell current flowing in the block bit line BBL with the reference current flowing in the reference bit line RBL.

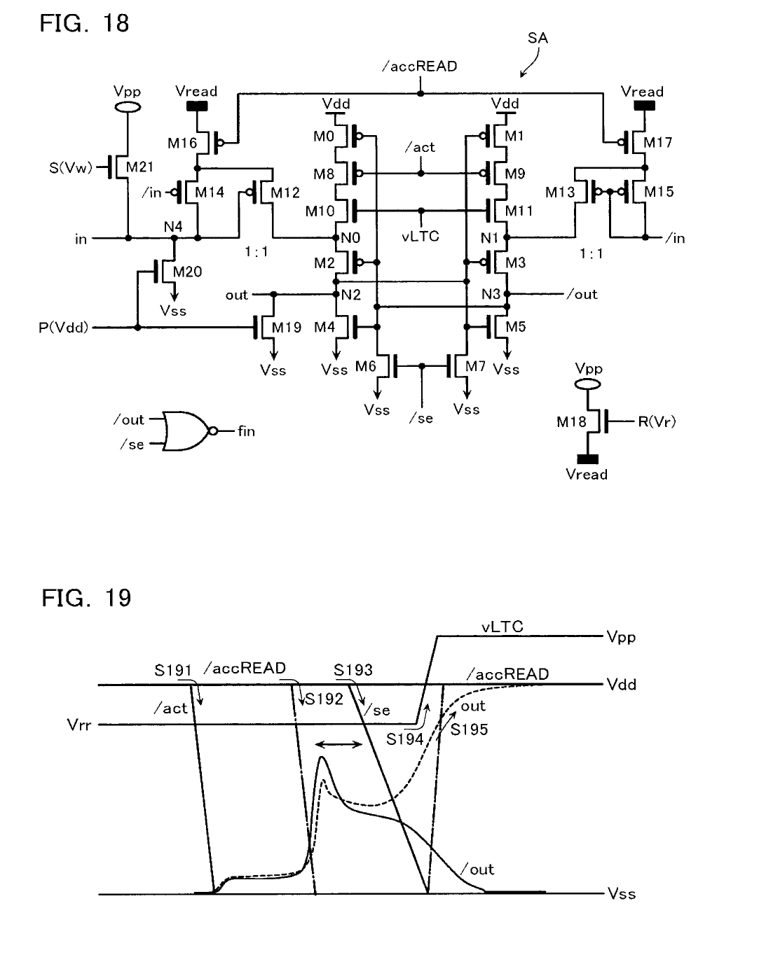

FIG. 18 is a circuit diagram of a sense amp in the memory system according to the embodiment.

The sense amp SA includes PMOS transistors M0-M3, M8, M9 and M12-M17, and NMOS transistors M4-M7, M10, M11 and M18-M21. The transistors M0, M8, M10, M2 and M4 are serially connected between a certain power source potential Vdd and the ground potential Vss. The transistor M6 has a source connected to the gates of the transistors M0, M2 and M4, and a drain connected to the ground potential Vss. The transistors M1, M9, M11, M3 and M5 are serially connected between the power source potential Vdd and the ground potential Vss. The transistor M7 has a source connected to the gates of the transistors M1, M3 and M5, and a drain connected to the ground potential Vss. The transistors M8 and M9 have gates, which receive a control signal, /act. The transistors M10 and M11 have gates, which receive a control signal, vLTC. The transistors M6 and M7 have gates, which receive a control signal, /se, for controlling the start of sense by the sense amp SA. An output node N2 between the transistors M2 and M4 is connected to the gates of the transistors M1, M3 and M5 and the source of the transistor M7. The output node N2 connects to an output signal ‘out’. An output node N3 between the transistors M3 and M5 is connected to the gates of the transistors M0, M2 and M4 and the source of the transistor M6. The output node N3 connects to an output signal ‘/out’.

The transistor M12 has a source connected to the drain of the transistor M16, a drain connected to an input node N0 between the transistors M10 and M2, and a gate connected to the drain of the transistor M14. The transistor M16 has a source connected to the read potential Vread, and a drain connected to the sources of the transistors M12 and M14. An input node N4 between the gate of the transistor M12 and the drain of the transistor M14 connects to an input signal ‘in’. The gate of the transistor M14 connects to an input signal ‘/in’.

The transistor M13 has a source connected to the drain of the transistor M17, a drain connected to an input node N1 between the transistors M11 and M3, and a gate connected to the drain and gate of the transistor M15. The transistor M17 has a source connected to the read potential Vread, and a drain connected to the sources of the transistors M13 and M15. The gate of the transistor M13 and the drain and gate of the transistor M15 connect to the input signal ‘/in’. The transistors M16 and M17 have gates, which receive a control signal, /accREAD.

The transistor M18 has a source connected to the potential Vpp, and a drain connected to the read potential Vread. The transistor M18 has a gate, which is set on a potential Vw at the time of write operation and on a potential Vr at the time of read operation.

The transistor M19 has a source connected to the output node N2, and a drain connected to the ground potential Vss. The transistor M19 has a gate, which is supplied with the power source potential Vdd at the time of program operation. The transistor M20 has a source connected to the input node N4, and a drain connected to the ground potential Vss. The transistor M20 has a gate, which is supplied with the power source potential Vdd at the time of program operation. The transistor M21 has a source connected to the power source potential Vdd, and a drain connected to the node N4. The transistor M21 has a gate, which is supplied with the write voltage Vw at the time of set operation.

This sense amp SA is operative to decide the resistance state of the cell by comparison between the cell current and the reference current, and is possible to achieve fast sure detection even by current comparison below several tens of nA.

The input stage of the sense amp SA includes a current mirror circuit composed of the transistors M12, M14 and M16, and a current mirror circuit composed of the transistors M13, M15 and M17. The flows of current in the input signal ‘/in’ and the input signal ‘in’ are equally configured. Thus, the sense amp SA receives the inflow of cell current, reflecting the amount of variation relative to the reference cell current, to perform current comparison at the point in time of the inflow of cell current. One input, in, receives a flow of the cell current and the other input, /in, receives a flow of the reference current.

The above two current mirror circuits operate on the voltage Vread. This voltage Vread is caused at the transistor M18 by limiting the potential Vpp and current. The transistor M18 is provided with the potential Vr at the time of read operation. Thus, the potential on the bit line BL at the time of read operation can be switched.

Next, basic operation of the sense amp SA is described.

FIG. 19 is an operating waveform diagram associated with the sense amp in the memory system according to the embodiment.

At first, when the control signal, /act, is lowered from ‘H’ to ‘L’ in a state of the control signal /se=“H” (step S191 in FIG. 19), the pair of transistors M8 and M9 turns on. This causes a flow of current in the sense amp SA.

Subsequently, the control signal, /accREAD, is lowered from ‘H’ to ‘L’ (step S192 in FIG. 19) to cause flows of current in the access bit line BL and the reference bit line RBL through the inputs of the input signals ‘in’ and ‘/in’. The difference between the cell current and the reference current flowing at this time is amplified and latched as the source voltage difference by the pair of transistors M6 and M7, which are cut off after passing from the linear region through the saturation region.

Amplification of the current difference between the cell current and the reference current requires lowering the control signal, /se, from ‘H’ to ‘L’ (step S193 in FIG. 19). Thus, the pair of transistors M6 and M7 passes from the linear region through the saturation region and turns off. At that time, the difference in timing of transition to the saturation region caused by the slight difference between the cell current and the reference current is converted into the source voltage. If the source potential on the transistor M6 is higher, the transistors M0 and M2 turn off because the gate potential on the transistors M0 and M2 becomes higher. If the source potential on the transistor M7 is higher, on the other hand, the transistors M1 and M3 turn off because the gate potential on the transistors M1 and M3 becomes higher. Thus, the difference in source voltage on the pair of transistors M6 and M7 is amplified.

The pair of transistors M10 and M11, of which gate potential is lowered at the initial period of sense to suppress the conductance, reduces the sense amp current from the power source potential Vdd. Thus, it reflects the cell current difference supplied via the pair of transistors M12 and M13 more strongly in accordance with the state of the sense amp SA.

At the initial period of sense, when the balance of the sense amp SA becomes stable after it was collapsed by the current difference between the cell current and the reference current, the control signal vLTC is raised from the potential Vrr to the potential Vpp higher than the power source potential Vdd (step S194 in FIG. 19). Thus, the sense amp SA is supplied with the power source voltage so that the output signal ‘out’ is fully swung to the power source potential Vdd (step S195 in FIG. 19). At this moment, the control signal /accREAD is raised to cut off the supply of the cell current and the reference current to the sense amp SA.

The pairs of fine-patterned transistors contained in the sense amp SA are given variations in accordance with fluctuations of production steps. Therefore, if the current path includes as many serially connected elements as possible, the variations can be cancelled. Therefore, the sense amp SA forms the configuration between the power source potential Vdd and the input nodes N0, N1 by three pairs of transistors, including the pair of transistors M0 and M1, the pair of transistors M8 and M9, and the pair of transistors M10 and M11. In particular, the pair of NMOS transistors M10 and M11 suppresses the influence of variations in the pair of PMOS transistors M0 and M1 and the pair of PMOS transistors M8 and M9 contained in a feedback loop for operation of the sense amp SA. Namely, the conductance of the NMOS transistors M10 and M11 is suppressed to elevate the potentials on the drains and sources of the PMOS transistors M0, M1, M8 and M9 located closer to the power source potential Vdd than these transistors M10 and M11, thereby raising the conductance of the PMOS transistors M0, M1, M8 and M9. In a word, the conductance of PMOS transistors and the conductance of NMOS transistors take action in directions effective in suppressing the influences of variations in respective characteristics. The gates of the pair of NMOS transistors M10 and M11 receive the control signal vLTC so that the above action becomes larger only when the control signal vLTC is amplified. Therefore, at the initial period of sense, the control signal vLTC is kept low. In the latter half of sense, in which data is determined, the control signal vLTC is elevated to raise the conductance of transistors in order to latch this data at high speeds. In the case of FIG. 19, the control signal vLTC is set to the potential Vrr different from the power source potential Vdd until immediately before latching after sense, and set to a much higher potential Vpp at the time of latching.

The time difference between the fall of the control signal /accREAD (step S192 in FIG. 19) and the fall of the control signal /se (step S193 in FIG. 19) is adjusted so that, after the fall of the control signal /accREAD, and when the cell current and reference current injected into the sense amp SA is sufficiently reflected on the input current to the sense amp SA, sense operation of the sense amp SA starts.

The sense amp SA generates the control signal, fin, indicative of the activation period thereof to external. The control signal, fin, is a signal that turns to ‘H’ in the case of /out=‘L’ and /se=‘L’ and that is utilized, for example, to disconnect the block bit line BBL from the sense amp SA.

Each MAT in the cell array includes plural bit lines BL, from which plural multilevel settable memory cells are hung down. Therefore, relations between these plural bit lines BL and MLDCs are described next. A memory system including a cell array of the cross point type is described here by way of example.

The herein-described relations between the bit lines BL and MLDCs are also applicable to a memory system configured to include selection lines extending from the control unit to memory cells, which are layered by selection levels. In this regard, the same goes for such a memory system that includes VBL-structured cell arrays having bit lines BL extending in the stacking direction of cell arrays.

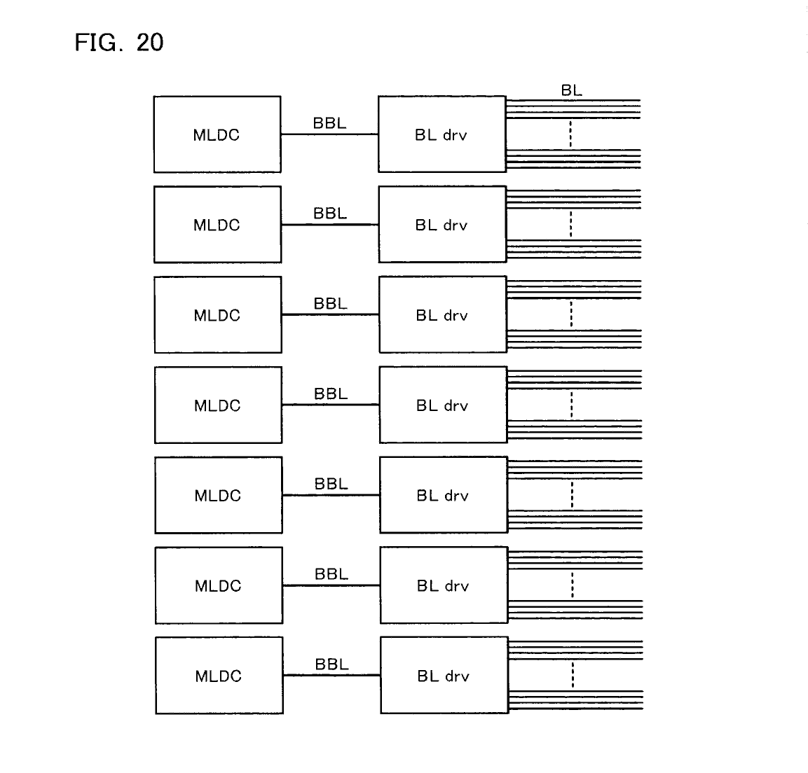

FIG. 20 is a diagram showing a configuration between bit lines and MLDCs in the memory system according to the embodiment.

Plural bit lines BL are grouped at every certain number into bit line blocks. Of plural bit line blocks, a half is driven from one side of the cell array and the other half from the other side of the cell array. The bit lines BL are selected, one line at each bit line block. For example, when eight bit lines BL configure a bit line block, bit lines BL equal to ⅛ of all bit lines BL driven from one side of the cell array can be selected simultaneously. On the assumption that bit lines BL can be selected from only one side of the cell array, bit lines BL equal to 1/16 of all bit lines BL can be selected in the cell array.

The column control circuit includes selection line block inner drivers having a decoder function of selectively connecting a selected bit line BL to a block bit line BBL. Hereinafter, this selection line block inner driver is referred to as a “BL dry circuit block”. This BL dry circuit block is described later.

Each block bit line BBL is connected to an MLDC. The work of this MLDC is effective in operating the state of the access cell as described before.

Plural MLDCs are operable in parallel. Therefore, bit lines BL can be contained in a bit line block by an appropriate number in consideration of the specification of the memory system and the restrictions on chip layouts and so forth.

The following description is given to an example of part of selection line drivers formed on a MAT contained in a TILE. The TILE herein is a structure of plural stacked MATs.

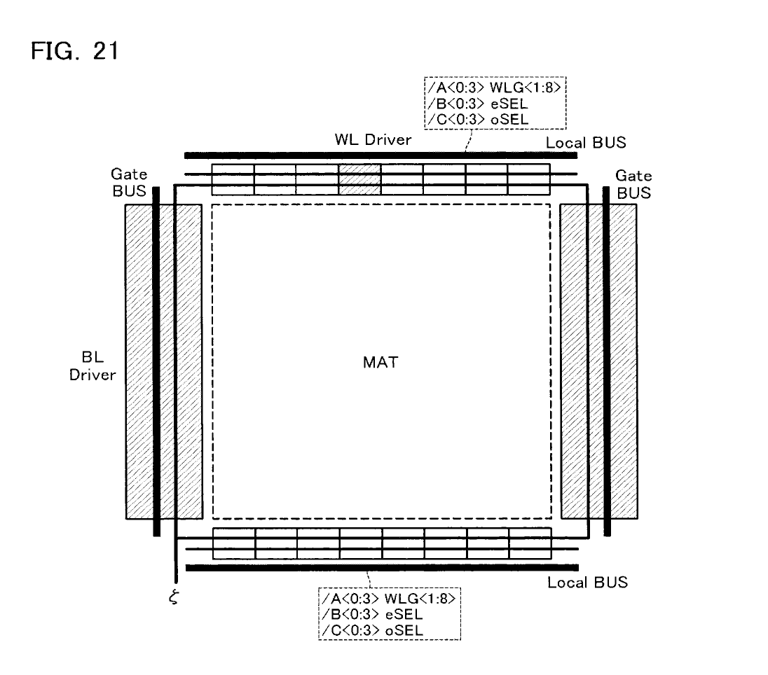

FIG. 21 is a diagram showing a functional block of the TILE and peripheral circuits in the memory system according to the embodiment. FIG. 21 shows the TILE in an almost square while the TILE may be rectangle, for example.

Selection line drivers located on the periphery of a MAT have almost the same configurations either on the bit line BL side or on the word line WL side. No difference exists between MATs. In access operation, however, bit lines BL are accessed, plural lines in parallel simultaneously. In contrast, word lines WL are accessed, only one line at each MAT. Therefore, decoders for the bit line driver and the word line driver on the TILE have a difference. In addition, the bit line driver is additionally provided with a MLDC connected to a block bit line BBL.

In FIG. 21, of the buses of signal lines that require decoding of access selection lines, the buses located on each MAT and having the same configuration for bit lines BL and for word lines WL are shown as the gate buses. In addition, selection line drivers operative to drive access selection lines are hatched. As described above, bit lines BL are driven, plural lines in parallel simultaneously. Accordingly, selection line drivers for bit lines BL are entirely hatched. On the other hand, word lines WL are driven, only one line at each MAT. Accordingly, only one selection line driver is hatched. The hatched selection line driver for the word line WL further performs decoding for accessing a certain word line WL. This decoder is formed not on the MAT but on the semiconductor substrate. A signal from this decoder is supplied via the local bus to each selection line driver. An example of signals required in the decoder shows /A<0:3>, /B<0:3>, /C<0:3>, eSEL, oSEL and WLG<1:8>. The roles of these signals are described later. In addition, each selection line driver is supplied with a voltage ζ from a common power source.

As described before, potentials on selection lines are set by selection line drivers. An increase in cell share, though, requires high-density alignment of these selection line drivers around the MAT. Therefore, a simplified layout of selection line drivers and a reduction in space become important.

Then, a configuration example of the BL dry circuit block contained in the bit line driver is described next.

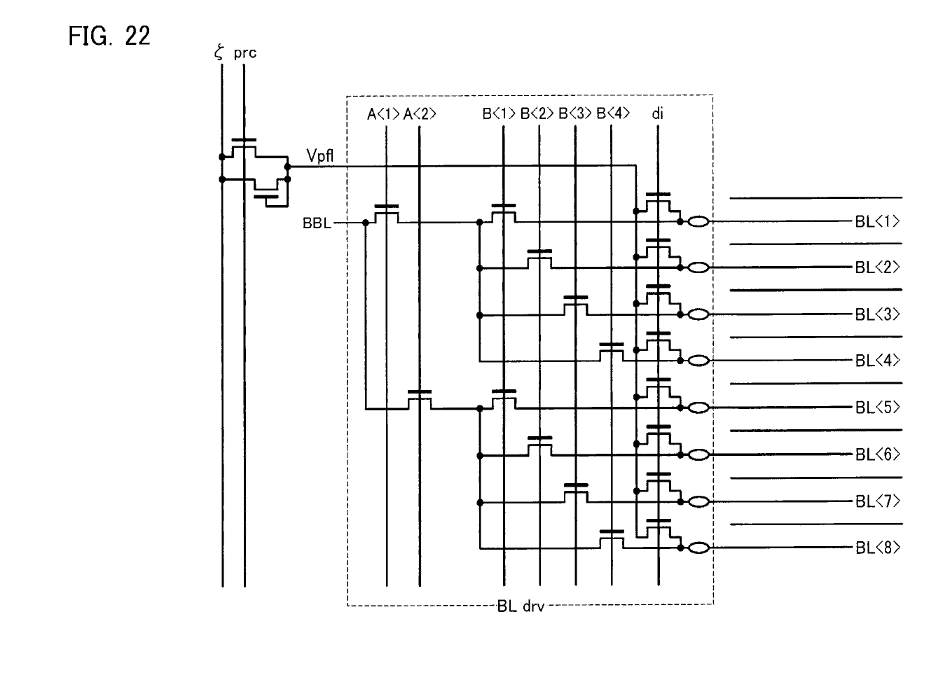

FIG. 22 is a circuit diagram of the BL dry circuit block in the memory system according to the embodiment.

FIG. 22 shows a circuit diagram in the case where BL dry circuit blocks are provided one by one at every 16 bit lines on the access side and on the non-access side. In a word, the number of selection lines taken in charge by one BL dry circuit block is equal to eight while the remaining eight bit lines are taken in charge by the BL dry circuit block on the opposite side. BL<1>-<8> shown in FIG. 22 indicate bit lines driven by one BL dry circuit block. In addition, ellipse parts in FIG. 22 indicate parts connected to vertical lines for connecting bit lines BL on each MAT to the BL dry circuit block. The TILE requires BL dry circuit blocks in proportion to the stacked MATs.

Whether the bit lines BL<1>-<8> are to be diode-connected to the power source ζ or not is determined by a signal, di. When this signal, di, is turned to ‘H’ and a signal, prc, is set at the potential ζ, the potential on the bit line BL fluctuates up/down by the threshold voltage Vth from the potential ζ to configure diode-connections of transistors that allow almost no current to flow in bit lines BL. Turning the signal, prc, to ‘H’ makes it possible to set the potential ζ on the bit line BL. When diode-connecting the transistors is intended, and when setting the bit lines BL on the potential ζ is intended, address signals A<1> and <2> and B<1>-<4> for selecting bit lines BL are all turned to ‘L’ to disconnect the bit lines BL from the signal line BBL.

When driving the access bit line is intended, the signal, di, is turned to ‘L’ at first to disconnect the bit lines BL from the power source ζ. Subsequently, the signals A<1> and <2> and B<1>-<4> are combined to select which bit line BL of the bit lines BL<1>-<8> is targeted as the access bit line. Then, the access bit line is connected to the block bit line BBL. When the signals A<1> and <2> and B<1>-<4> are fed to all BL dry circuit blocks in common, bit lines BL can be selected simultaneously, one at each BL dry circuit block. In contrast, if signals A<1> and <2> and B<1>-<4> are fed separately to groups of BL dry circuit blocks, the number of simultaneously selectable bit lines BL can be adjusted.

The signal BBL is a signal that is used in driving the bit line BL and monitoring the state of the memory cell MC, and that is fed to the sense amp and the access circuit.

The signal line BBL is provided with the set potential Vset, the ground potential Vss and the potential ζ in accordance with data to be written in a memory cell MC. Simultaneously selected bit lines BL are provided with the potentials Vset, Vss and ζ via this signal line BBL separately and simultaneously.

The following description is given to a configuration example of a WL dry circuit block contained in the word line driver.

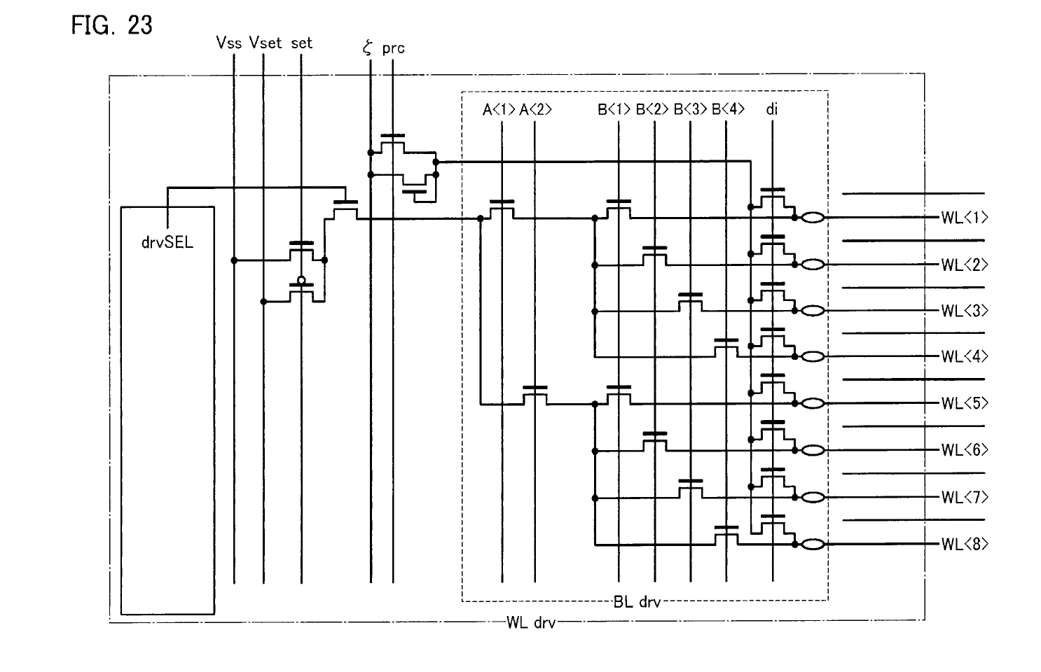

FIG. 23 is a circuit diagram of the WL dry circuit block in the memory system according to the embodiment. A circuit surrounded by the chain line in the figure is the WL dry circuit block.

Word lines WL are selected, only one line on a MAT. In contrast, bit lines BL are selected, one line at each bit line block and plural lines in parallel as a whole. Then, if the input signals BBL can be reduced to one on the access side of the MAT, the configuration of the BL dry circuit block is applicable to the WL dry circuit block.

The WL dry circuit block includes the BL dry circuit block shown in FIG. 22 and additionally includes a drvSEL circuit block operative to select one BL dry circuit block.

The outputs from the WL dry circuit block connect to word lines WL<1>-<8>. The WL dry circuit block sets the access word line WL on the ground potential Vss or the potential Vset. This switching is performed by a signal, set. This signal, set, is used to control an Nch transistor and a Pch transistor to supply the ground potential Vss or the set potential Vset from the drvSEL circuit block to the BL dry circuit block via a switching transistor. The switching transistor can be on/off-controlled by a signal, drvSEL, output from the drvSEL circuit block.

Finally, a circuit operative to select one word line WL from the MAT, that is, the drvSEL circuit block is described.

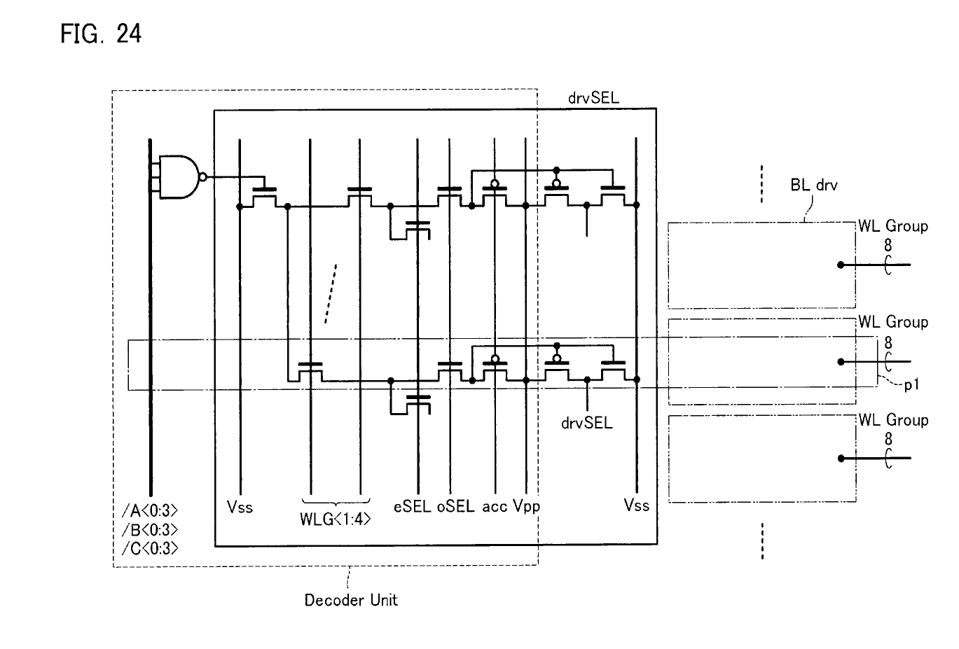

FIG. 24 is a circuit diagram of the drvSEL circuit block in the memory system according to the embodiment.

The output from the drvSEL circuit block is the signal drvSEL as described above. When non-selection of a BL dry circuit block is intended, the signal drvSEL turns to ‘L’ to bring the input of the BL dry circuit block into the floating state. The drvSEL circuit block, the signal drvSEL, receives a decoding-state indicative signal on the gates of Pch transistors and Nch transistors, and connects the signal drvSEL to the ground potential Vss or to the power source of the potential Vpp higher than the set voltage Vset.

As shown by the dashed-line square in FIG. 24, part of the drvSEL circuit block and a NAND circuit configure a decoder unit. The decoder unit receives signals eSEL, oSEL and WLG<1:4> for discharging the power source potential Vpp, a signal, acc, for precharging to the power source potential Vpp, and the output from the NAND circuit that decodes address signals /A<0:3>, /B<0:3> and /C<0:3>. Namely, the decoder unit uses the signals eSEL, oSEL and WLG<1:4> to select one of eight BL dry circuit blocks. In addition, it decodes the signals /A<0:3>, /B<0:3> and /C<0:3> to select one drvSEL circuit block. Therefore, in the case of the example shown in FIG. 21, one side of the MAT includes 8×4³=512 word line groups of eight word lines WL. The signal, acc, turns to ‘H’ at the selection line driver on the access side for selecting the access word line WL to stop precharging to the decoder unit. The decoder unit includes a serial circuit pl of plural transistors each controlled by any of the signal eSEL or oSEL, one of the signals WLG<1:4>, and the output from the NAND circuit. The charge on the precharge node can be discharged to the ground potential Vss via this serial circuit p1. In this case, p1 shown by the chain line is coincident with the chain line shown in FIG. 23.

### CONCLUSION

As described above, in the case of the embodiment, the use of access in the time-dividing method makes it possible to realize a multi-valued memory cell capable of storing data in accordance with electrically hard-to-detect physical states. In a word, the embodiment makes it possible to realize a higher storage density memory system even with the use of the ion memory and so forth.

### OTHERS

While the embodiments of the present invention have been described, these embodiments are presented by way of example and are not intended to limit the scope of the invention. These novel embodiments can be implemented in a variety of other forms, and various omissions, substitutions and changes can be made without departing from the spirit of the invention. These embodiments and variations thereof would fall within the scope and spirit of the invention and also fall within the invention recited in claims and equivalents thereof.

What is claimed is:

1. A memory system, comprising a memory cell having plural transitionable physical states,
said plural physical states including a certain physical state defined as a first physical state, and a physical state held in said memory cell defined as a second physical state, and
said memory cell storing plural different data in accordance with differences in transition time from said second physical state to said first physical state.

2. The memory system according to claim 1, further comprising a control unit operative to execute a read sequence of reading data from said memory cell,
wherein said control unit executes read operation at the time of said read sequence to cause said memory cell in said second physical state to make a transition to said first physical state and then decide data in said memory cell based on the transition time.

3. The memory system according to claim 2, wherein said control unit decides data in said memory cell at the time of said read operation in said read sequence based on a time range, within which said transition time falls, of plural predetermined time ranges sectioned at even intervals.

4. The memory system according to claim 2, wherein said control unit executes rewrite operation after said read operation in said read sequence to cause said memory cell in said first physical state to make a transition to said second physical state.

5. The memory system according to claim 1, further comprising a control unit operative to execute a write sequence of writing data in said memory cell,
wherein said control unit executes write operation at the time of said write sequence to cause said memory cell in said first physical state to make a transition of the physical state by the transition time based on write-intended data.

6. The memory system according to claim 5, wherein said plural data are assigned to plural predetermined even-interval transition time,
wherein said control unit causes said memory cell to make a transition of the physical state by the transition time assigned to write-intended data at the time of said write operation in said write sequence.

7. The memory system according to claim 5, wherein said control unit executes initializing operation to cause said memory cell to make a transition to said first physical state prior to said write operation in said write sequence.

8. The memory system according to claim 7, wherein said plural physical states include a physical state defined as a third physical state, which requires the longest time for a transition from said first physical state,
wherein said control unit causes said memory cell to make a transition to said third physical state prior to the transition to said first physical state at the time of said initializing operation in said write sequence.

9. The memory system according to claim 1, wherein the physical state of said memory cell is the length of a filament.

10. The memory system according to claim 9, wherein said memory cell includes a holding functional layer in which said filament expands and contracts on application of electric energy, said holding functional layer containing uneven layers by the number corresponding to said plural data.

11. A memory system, comprising a memory cell having plural physical states,
said memory cell having an on-state that causes a flow of current and an off-state that causes no flow of current, and
said memory cell storing plural data as assigned to plural physical states having the same on/off-states relative to voltages.

12. The memory system according to claim 11, further comprising a control unit operative to execute a read sequence of reading data from said memory cell,
wherein said control unit executes read operation at the time of said read sequence to decide data in said memory cell based on the transition time since the beginning of application of a voltage until said on/off-state makes a transition.

13. The memory system according to claim 12, wherein said control unit decides data in said memory cell at the time of said read operation in said read sequence based on a time range, within which said transition time falls, of plural predetermined time ranges sectioned at even intervals.

14. The memory system according to claim 11, further comprising a control unit operative to execute a write sequence of writing data in said memory cell,
wherein said control unit executes write operation at the time of said write sequence to apply a voltage to said memory cell by the transition time based on write-intended data.

15. The memory system according to claim 14, wherein said plural data are assigned to plural predetermined even-interval transition time,
wherein said control unit applies a voltage to said memory cell by the transition time assigned to write-intended data at the time of said write operation in said write sequence.

16. A method of operation of a memory system, said memory system including
a memory cell having plural transitionable physical states, and
a control unit operative to execute a read sequence of reading data from said memory cell,
wherein said plural physical states include a certain physical state defined as a first physical state, and a physical state held in said memory cell defined as a second physical state, said method comprising:
using said control unit to execute read operation at the time of said read sequence to cause said memory cell in said second physical state to make a transition to said first physical state and then decide data in said memory cell based on the transition time.

17. The method of operation of a memory system according to claim 16, further comprising:
using said control unit to decide data in said memory cell at the time of said read operation in said read sequence based on a time range, within which said transition time falls, of plural predetermined time ranges sectioned at even intervals.

18. The method of operation of a memory system according to claim 17, further comprising:
using said control unit to execute rewrite operation after said read operation in said read sequence to cause said memory cell in said first physical state to make a transition to said second physical state.

19. The method of operation of a memory system according to claim 16, further comprising:
using said control unit to execute a write sequence of writing data in said memory cell; and
using said control unit to execute write operation at the time of said write sequence to cause said memory cell in said first physical state to make a transition of the physical state by the transition time based on write-intended data.

20. The method of operation of a memory system according to claim 19, wherein said plural data are assigned to plural predetermined even-interval transition time, said method further comprising:
using said control unit to cause said memory cell to make a transition of the physical state by the transition time assigned to write-intended data at said write operation in said write sequence.
